(19) United States
(12) Patent Application Publication
(10) Pub. No.: US 2016/0329213 A1
(43) Pub. Date: Nov. 10, 2016

(54) HIGHLY SELECTIVE DEPOSITION OF AMORPHOUS CARBON AS A METAL DIFFUSION BARRIER LAYER

(71) Applicant: Lam Research Corporation, Fremont, CA (US)

(72) Inventors: Wei Tang, Fremont, CA (US); Jason Daejin Park, San Jose, CA (US); Patrick A. Van Cleemput, San Jose, CA (US); Yezdi Dordi, Palo Alto, CA (US)

(21) Appl. No.: 15/095,258

(22) Filed: Apr. 11, 2016

Related U.S. Application Data
(60) Provisional application No. 62/156,597, filed on May 4, 2015.

(51) Int. Cl. H01L 21/285; H01L 21/3213; H01L 21/768

(52) U.S. Cl. CPC H01L 21/28562; H01L 21/76802; H01L 21/76843; H01L 21/76879; H01L 21/32131

(57) ABSTRACT

A method for providing a metal diffusion barrier layer comprising providing a substrate including a metal layer; depositing a dielectric layer on the metal layer; defining a feature in the dielectric layer, wherein the feature includes side walls defined by the dielectric layer and a bottom surface defined by the metal layer; selectively depositing a metal diffusion barrier layer on the side walls of the feature and not depositing the metal diffusion barrier layer on the bottom surface of the feature, wherein the metal diffusion barrier layer includes amorphous carbon; and depositing metal in the feature.

### CROSS-REFERENCE TO RELATED APPLICATIONS

This application claims the benefit of U.S. Provisional Application No. 62/156,597, filed on May 4, 2015. The entire disclosure of the application referenced above is incorporated herein by reference.

### FIELD

The present disclosure relates to substrate processing systems, and more particularly to selective deposition of amorphous carbon as a metal diffusion barrier layer.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Referring now to FIG. 1, a substrate 10 includes a metal layer 12 such as copper (Cu) and a dielectric layer 14 arranged on the metal layer 12. A mask layer 16 is deposited on the dielectric layer 14 and is patterned for subsequent etching. A feature 18 such as a via is etched through an opening in the mask layer 16 into the dielectric layer 14 down to the metal layer 12. Subsequently, a metal diffusion barrier layer 20 that is conformal is deposited. In some examples, the metal diffusion barrier layer 20 includes a tantalum nitride (TaN) layer 22 and a tantalum (T) layer 24. The metal diffusion barrier layer 20 prevents metal diffusion into the dielectric layer 14.

Referring now to FIG. 2, the feature 18 is filled with metal such as copper as shown at 26. Even if the metal diffusion barrier layer 20 is very thin, it still contributes a significant portion of the resistance of the via (at locations identified by reference number 30) due to electron scattering at interfaces thereof. Amendment approaches such as via bottom etch back may be used to reduce the resistance of the feature 18. However, this approach complicates the process flow and does not completely remove the barrier material at the bottom the feature 18. Therefore, these methods do not significantly reduce contact resistance.

### SUMMARY

A method for providing a metal diffusion barrier layer includes providing a substrate including a metal layer; depositing a dielectric layer on the metal layer; defining a feature in the dielectric layer, wherein the feature includes side walls defined by the dielectric layer and a bottom surface defined by the metal layer; selectively depositing a metal diffusion barrier layer on the side walls of the feature, wherein the metal diffusion barrier layer includes amorphous carbon; and depositing metal in the feature.

In other features, the selectively depositing the metal diffusion barrier layer includes not depositing the metal diffusion barrier layer on the bottom surface of the feature. Defining the feature further includes depositing and patterning a mask layer on the dielectric layer; and etching exposed portions of the dielectric layer to define the feature. Depositing the metal diffusion barrier layer is performed using high density plasma chemical vapor deposition (HDP-CVD). Depositing the metal diffusion barrier layer includes supplying a plasma process gas mixture including methane and helium during the HDP-CVD. A ratio of methane to helium is less than 0.15. A ratio of methane to helium is less than 0.10. A ratio of methane to helium is less than 0.05.

In other features, depositing the metal diffusion barrier layer includes supplying a plasma process gas mixture including acetylene and molecular hydrogen during the HDP-CVD. The HDP-CVD is performed in a processing chamber including a dome-shaped chamber, a coil arranged on an outer surface of the dome-shaped chamber and a pedestal arranged inside of the dome-shaped chamber. The method includes biasing the coil by supplying first RF power at a first frequency and second RF power at a second frequency. The first frequency is lower than the second frequency. A combined RF power of the first RF power and the second RF power is in a range between 2000 W and 4000 W. The first frequency is 360 kHz and the second frequency is 400 kHz.

In other features, the method includes biasing the coil by supplying RF power at a first frequency. The RF power is in a range between 2000 W and 4000 W. The first frequency is 400 kHz.

In other features, the pedestal includes an embedded electrode, and the method further includes biasing the embedded electrode by supplying RF power at a first frequency. The RF power is supplied in a range between 500 W and 2250 W. The first frequency is 13.56 MHz.

In other features, the method includes controlling a process temperature while depositing the metal diffusion barrier layer to less than or equal to 200° C.

In other features, the method includes controlling a process temperature while depositing the metal diffusion barrier layer to a range between 80° C. and 180° C. The method includes setting a deposition rate of the metal diffusion barrier layer to a range between 50 Angstroms (A)/minute and 200 A/min.

In other features, depositing the metal diffusion barrier layer occurs using a hybrid mechanism in which the metal diffusion barrier layer is both deposited and eroded by sputtering.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of a substrate according to the prior art;

FIG. 2 is a side cross-sectional view of the substrate of FIG. 1 after metal fill according to the prior art;

FIG. 3 is a side cross-sectional view of an example of a substrate according to the present disclosure;

FIG. 4 is a side cross-sectional view of the example of the substrate of FIG. 3 after metal fill according to the present disclosure;

FIGS. 5 and 6 are flowcharts illustrating an example of a method for depositing a selective metal diffusion barrier layer according to the present disclosure; and

FIG. 7 is a functional block diagram of an example of a high density plasma (HDP) chemical vapor deposition (CVD) substrate processing system according to the present disclosure.

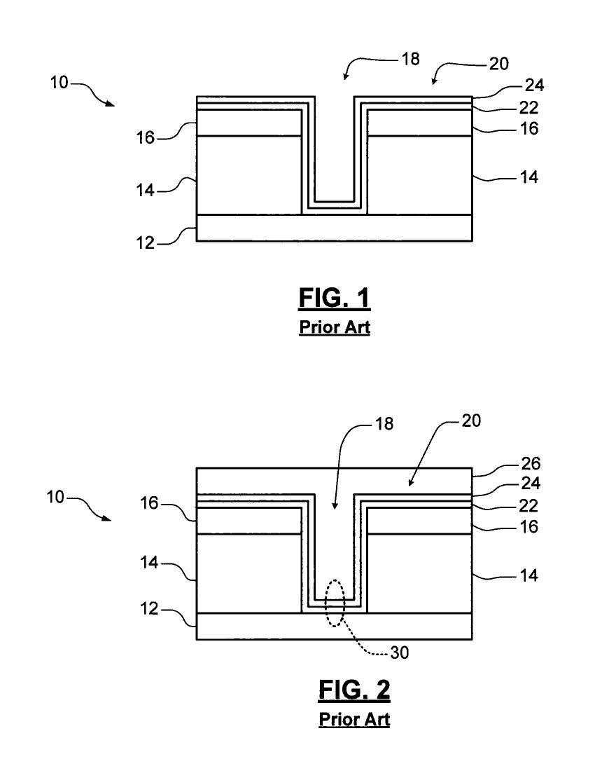

In the drawings, reference numbers may be reused to identify similar and/or identical elements.

### DETAILED DESCRIPTION

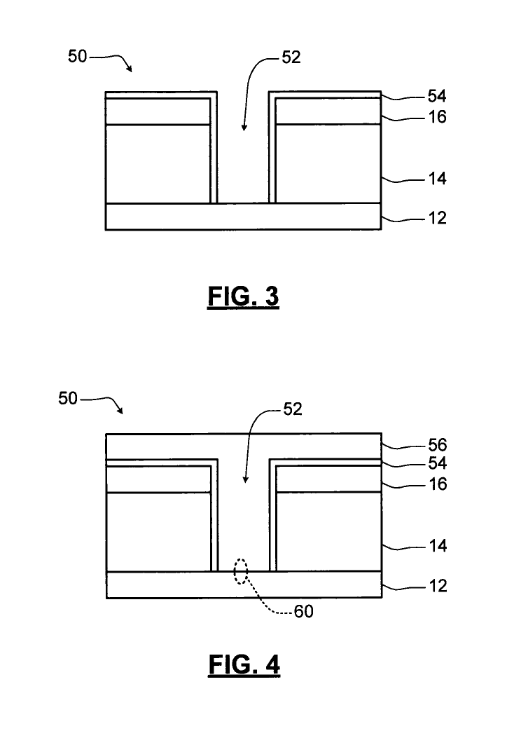

Referring now to FIG. 3, a substrate 50 includes the metal layer 12 and a dielectric layer 14 arranged on the metal layer 12. In some examples, the dielectric layer 14 is a low k or ultra-low k (ULK) dielectric material. The mask layer 16 is deposited on the dielectric layer 14 and is patterned for subsequent etching. A feature 52 such as a via is etched through openings in the mask layer 16 into the dielectric layer 14 down to the metal layer 12.

Subsequently, a metal diffusion barrier layer 54 including amorphous carbon is selectively deposited using a plasma process such as high density plasma chemical vapor deposition (HDP-CVD). The metal diffusion barrier layer 54 prevents metal diffusion into the dielectric layer 14. The metal diffusion barrier layer 54 is selectively deposited in a field region of the mask layer 16 and on side walls of the feature 52 but not on a bottom surface of the feature 52.

Referring now to FIG. 4, the feature 52 is filled with metal such as Cu as shown at 56. The resistance of the feature 52 (at locations identified by reference number 60) is substantially reduced as compared to the substrate 10 in FIG. 2.

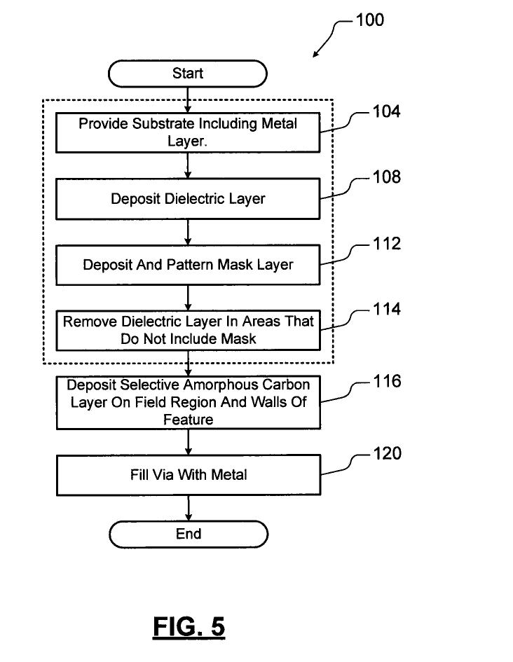

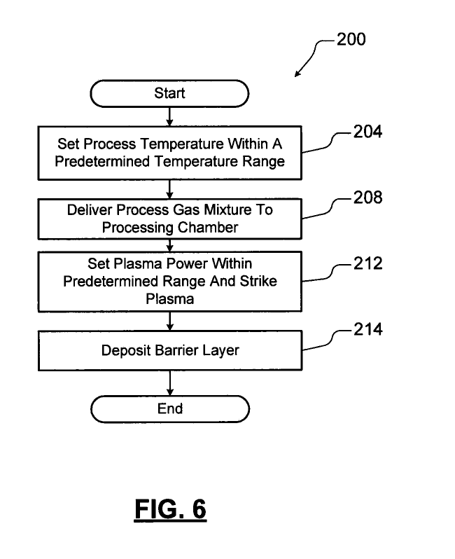

Referring now to FIGS. 5 and 6, examples of methods for processing the substrate 50 are shown. In FIG. 5, a method 100 is shown and includes providing a substrate including a metal layer at 104. A low k or ULK dielectric layer is deposited on the metal layer at 108. At 112, a mask layer is deposited and patterned. At 114, portions of the dielectric layer are removed in areas that do not include a mask. For example, wet or dry etching may be used to remove the portions of the dielectric layer. At 116, an amorphous carbon layer is selectively deposited on field regions of the mask layer and walls of the feature but not upon a bottom surface of the feature. At 120, the feature is filled with metal such as copper.

In FIG. 6, an example of a method 200 for depositing the metal diffusion barrier layer including amorphous carbon (step 116) is shown. At 204, the process or substrate temperature is set within a predetermined temperature range. At 208, process gas is delivered to the processing chamber. In some examples, the processing chamber performs HDP-CVD. At 212, plasma RF power is set within a predetermined range and plasma is struck. At 214, the metal diffusion barrier layer is deposited.

In some examples, the process gas mixture includes methane (CH₄) and helium (He), although other process gas mixtures may be used. In some examples, CH₄ is diluted by He to produce a relatively low deposition rate (˜150 A/min) because the target application is usually a relatively thin layer. In some examples, CH₄ is supplied at 30 sccm and He is supplied at 1000 sccm. In some examples, the source power (low frequency (LF) and medium frequency (MF)) is set to 3000 W and high frequency (HF) biasing power is set to 1000 W. In some examples, the HF power is lower than a typical HDP oxide process (>2500 W). In some examples, temperature is less than 200° C. to maximize the amorphicity for improved barrier properties. In some examples, the amorphous carbon deposition and etch occurs simultaneously on the Cu substrate.

More generally, in some examples, (LF+MF) power is set in a range from 2000 W to 4000 W. HF power is set within a range from 500 W to 2250 W. In some examples, CH₄ and He are supplied at a ratio less than or equal to 0.15, 0.10 or 0.05. In some examples, process temperature is set within a range from 80° C. to 180° C. In some examples, the deposition rate is set in a range from 50 Angstroms (A)/min to 200 A/min. The specific values that are used will depend somewhat on the particular process chemistry and processing chamber that is used. If the HF power is too low, the amorphous carbon deposited on the Cu layer may not be etched too much. If HF power is too high, the amorphous carbon on dielectric layer may be etched. Both cases reduce the deposition selectivity. Also, if the deposition rate is too high, then the amorphous carbon film may nucleate on the Cu substrate more easily.

In other examples, the process gas mixture may include acetylene (C₂H₂) and molecular hydrogen (H₂). C₂H₂ is less H-rich than CH₄. If using less H-rich carbon precursor than CH₄, blending in H₂ may be used to improve selectivity.

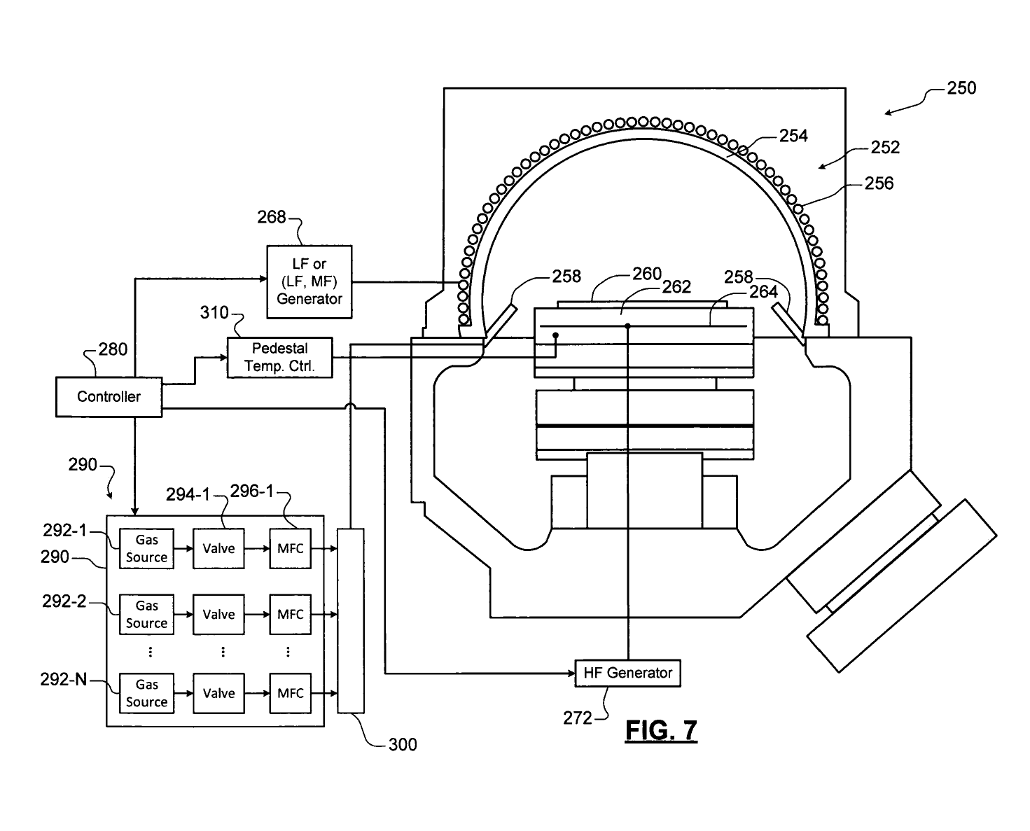

In FIG. 7, an example of a substrate processing system 300 for depositing the metal diffusion barrier layer using a plasma process such as HDP-CVD is shown. The deposition of dielectric films in the HDP-CVD reactor typically occurs by a hybrid mechanism in which material is simultaneously deposited by plasma enhanced chemical vapor deposition chemistry and eroded by sputtering to provide a desired film profile within a feature.

For example only, a suitable HDP-CVD system is shown in “Induction Plasma Source”, U.S. Pat. No. 5,405,480, which issued on Apr. 11, 1995 and is assigned to Novellus Systems Inc. or “Method of Forming Nitride Films With High Compressive Stress For Improved PFET Device Performance”, U.S. Pat. No. 7,491,660 which issued on Feb. 17, 2009 and is assigned to Novellus Systems Inc., both of which are hereby incorporated by reference in their entirety. While inductively coupled HDP-CVD is described, other plasma processes such as any inductively or capacitively coupled plasma enhanced chemical vapor deposition (PECVD) process may be used.

The example HDP-CVD substrate processing system 250 in FIG. 7 includes a substrate processing chamber 252 that encloses components of the substrate processing chamber 250 and contains the RF plasma. The substrate processing chamber 252 includes a dome-shaped chamber 254. An inductive coil 256 is arranged around an outer surface of the dome-shaped chamber 254. Gas injectors 258 are arranged around a pedestal 262 to supply gas in the dome-shaped chamber 254. The inductive coil 256 is excited by RF power to generate a magnetic field that creates plasma in the processing chamber.

In some examples, the gas injectors 258 include an array of gas injectors that are arranged around a periphery of the pedestal 262 at spaced intervals. The pedestal 262 supports a substrate 260 and includes an electrode 264. A signal generator 268 generates low frequency (LF) signals or LF and medium frequency (MF) signals that are output to the inductive coil 256. For example, the signal generator 268 may generate LF signals at 360 kHz and MF signals at 400 kHz at a combined power in a range from 2000 W to 4000 W. Alternately, a single signal at 400 kHz at a power in a range from 2000 W to 4000 W can be used. A signal generator 272 generates high frequency (HF) signals that are output to the electrode 264. For example, the signal generator 272 generates HF signals at 13.56 MHz at a power in a range from 500 W to 2250 W.

A controller 280 communicates with and controls the signal generators 268 and 272 as needed. The controller 280 further communicates with and controls a gas delivery system 290 to deliver process gas mixtures and/or purge gas as needed. The gas delivery system 290 includes one or more gas sources 292-1, 292-2, . . . , and 292-N (collectively gas sources 292), where N is an integer greater than zero. The gas sources supply one or more precursors and mixtures thereof. The gas sources may also supply purge gas. In some examples, the gas sources 292 are connected by valves 294-1, 294-2, . . . , and 294-N (collectively valves 294) and mass flow controllers 296-1, 296-2, . . . , and 296-N (collectively mass flow controllers 296) directly to the processing chamber and/or to a manifold 300, although other gas delivery systems may be used. An output of the manifold 300 is fed to the gas injectors 258.

The controller 280 further communicates with a pedestal temperature control system 310. The pedestal temperature control system 310 may include a heater, a cooler or a heater and a cooler that may be used to control a temperature of the substrate 260 during processing. A valve and a pump (both not shown) may be used to control pressure in the chamber and/or to evacuate reactants from the processing chamber. In some examples, the process is performed at vacuum pressure.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for providing a metal diffusion barrier layer comprising:
providing a substrate including a metal layer;
depositing a dielectric layer on the metal layer;
defining a feature in the dielectric layer, wherein the feature includes side walls defined by the dielectric layer and a bottom surface defined by the metal layer;
selectively depositing a metal diffusion barrier layer on the side walls of the feature, wherein the metal diffusion barrier layer includes amorphous carbon; and
depositing metal in the feature.

2. The method of claim 1, wherein selectively depositing the metal diffusion layer includes not depositing the metal diffusion barrier layer on the bottom surface of the feature.

3. The method of claim 1, wherein defining the feature further includes:
depositing and patterning a mask layer on the dielectric layer; and
etching exposed portions of the dielectric layer to define the feature.

4. The method of claim 1, wherein depositing the metal diffusion barrier layer is performed using high density plasma chemical vapor deposition (HDP-CVD).

5. The method of claim 4, wherein depositing the metal diffusion barrier layer includes supplying a plasma process gas mixture including methane and helium during the HDP-CVD.

6. The method of claim 5, wherein a ratio of methane to helium is less than 0.15.

7. The method of claim 5, wherein a ratio of methane to helium is less than 0.10.

8. The method of claim 5, wherein a ratio of methane to helium is less than 0.05.

9. The method of claim 4, wherein depositing the metal diffusion barrier layer includes supplying a plasma process gas mixture including acetylene and molecular hydrogen during the HDP-CVD.

10. The method of claim 4, wherein the HDP-CVD is performed in a processing chamber including a dome-shaped chamber, a coil arranged on an outer surface of the dome-shaped chamber and a pedestal arranged inside of the dome-shaped chamber.

11. The method of claim 10, further comprising biasing the coil by supplying first RF power at a first frequency and second RF power at a second frequency, wherein the first frequency is lower than the second frequency, and wherein a combined RF power of the first RF power and the second RF power is in a range between 2000 W and 4000 W.

12. The method of claim 11, wherein the first frequency is 360 kHz and the second frequency is 400 kHz.

13. The method of claim 10, further comprising biasing the coil by supplying RF power at a first frequency, wherein the RF power is in a range between 2000 W and 4000 W.

14. The method of claim 13, wherein the first frequency is 400 kHz.

15. The method of claim 10, wherein the pedestal includes an embedded electrode, and further comprising biasing the embedded electrode by supplying RF power at a first frequency.

16. The method of claim 15, wherein the RF power is supplied in a range between 500 W and 2250 W.

17. The method of claim 15, wherein the first frequency is 13.56 MHz.

18. The method of claim 4, further comprising controlling a process temperature while depositing the metal diffusion barrier layer to less than or equal to 200° C.

19. The method of claim 4, further comprising controlling a process temperature while depositing the metal diffusion barrier layer to a range between 80° C. and 180° C.

20. The method of claim 1, further comprising setting a deposition rate of the metal diffusion barrier layer to a range between 50 Angstroms (A)/minute and 200 A/min.

21. The method of claim 4, wherein depositing the metal diffusion barrier layer occurs using a hybrid mechanism in which the metal diffusion barrier layer is both deposited and eroded by sputtering.
